(19) United States
(12) Patent Application Publication
(10) Pub. No.: US 2005/0253214 A1
(43) Pub. Date: Nov. 17, 2005

(54) Solid-state imaging device

(75) Inventors: Hiroki Nagasaki, Kyoto (JP); Syouji Tanaka, Ikoma (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/039,782

(22) Filed: Jan. 24, 2005

(30) Foreign Application Priority Data
May 13, 2004 (JP) 2004-143789

(51) Int. Cl. H01L 31/06

(52) U.S. Cl. 257/462

(57) ABSTRACT

Photodiodes 20a and 20b are formed in the main surface of the semiconductor substrate 10. The photodiode 20a includes a P⁺-type surface layer 22a and a charge accumulating portion 21a, and the photodiode 20b includes a P⁺-type surface layer 22b and a charge accumulating portion 21b. The photodiodes 20a and 20b are separated by an element isolating portion 33a having an STI structure. The bottom portions of the charge accumulating portions 21a and 21b constituting the photodiodes 20a and 20b are located in a deeper position from the main surface of the semiconductor substrate 10 than the bottom portions of the element isolating portion 33a. Thus, a solid-state imaging device in which color mixing can be prevented and the capacity of the charge accumulating portions is large, and the sensitivity and the saturation characteristics are excellent can be provided.

### BACKGROUND OF THE INVENTION

1. Field of the Invention

The present invention relates to a solid-state imaging device. More specifically, the present invention relates to a solid-state imaging device in which elements are isolated by the STI (shallow trench isolation) method.

2. Description of the Background Art

In recent years, a solid-state imaging device employing an amplification type MOS sensor has attracted attention as a solid-state imaging device. This solid-state imaging device amplifies a signal detected in a photodiode for every pixel with a transistor and is characterized by having high sensitivity. Furthermore, in the solid-state imaging device, with recent miniaturization of pixels, an element isolation structure by the STI method is used. The STI method is a method of forming a groove in the main surface of a semiconductor substrate, filling an insulating film such as an oxide film in this groove and then smoothing the surface so that an element isolating portion is formed. In this STI method, the side faces of the groove can be formed to be sharp with respect to the main surface of the semiconductor substrate, and therefore the width of the element isolating portion can be narrower that that of an element isolating portion formed by the LOCOS (local oxidization of silicon) method.

Hereinafter, the structure of a conventional solid-state imaging device will be described with reference to FIG. 8. FIG. 8 is a cross-sectional view of a solid-state imaging device employing an amplification type MOS sensor in which elements are isolated by the STI method.

The solid-state imaging device shown in FIG. 8 includes a semiconductor substrate 10, photodiodes 20a and 20b, and a high voltage transistor 70. The semiconductor substrate 10 is a substrate that serves as a base for forming a solid-state imaging device and is constituted by a P-type semiconductor layer. The photodiode 20a is formed in the main surface of the semiconductor substrate 10 and generates signal charges having a charge amount in accordance with the intensity of incident light that is directed to the main surface of the semiconductor substrate 10 and accumulates the generated signal charges. The photodiode 20a includes a surface layer 22a formed in the vicinity of the surface of the semiconductor substrate 10 and a charge accumulating portion 23a formed below the surface layer 22a.

The surface layer 22a is a P-type impurity layer having a larger impurity concentration than that of the semiconductor substrate 10. Hereinafter, such a large P-type impurity concentration is represented by P⁺ type and the surface layer 22a is referred to as “P⁺-type surface layer 22a”. The P⁺-type surface layer 22a is formed by introducing P-type impurities in the main surface of the semiconductor substrate 10 by ion implantation. The charge accumulating portion 23a is an N-type impurity layer, and forms a PN junction with the P⁺-type surface layer 22a so that the charge accumulating portion 23a generates signal charges having a charge amount in accordance with the intensity of incident light and accumulates the generated signal charges. The charge accumulating portion 23a is formed by introducing N-type impurities to the main surface of the semiconductor substrate 10 by ion implantation and diffusing thermally the introduced impurities. The photodiode 20b has the same structure as that of the photodiode 20a, so that the description thereof is omitted.

The high voltage transistor 70 includes a source diffusion layer 40a, a drain diffusion layer 40b, a gate insulating film 50 and a gate electrode 60. The source diffusion layer 40a and the drain diffusion layer 40b are formed by introducing N-type impurities to the main surface of the semiconductor substrate 10 by ion implantation. The gate insulating film 50 is formed of a silicon oxide film or the like on the surface of the semiconductor substrate 10 in an area between the source diffusion layer 40a and the drain diffusion layer 40b. The gate electrode 60 is formed of a polysilicon film or the like on the gate insulating film 50.

The photodiodes 20a and 20b and the high voltage transistor 70 are isolated by element isolating portions 33a and 33b formed by the STI method. More specifically, the photodiodes 20a and 20b are isolated by the element isolating portion 33a. The photodiode 20b and the high voltage transistor 70 are isolated by the element isolating portion 33b. The element isolating portions 33a and 33b will be described in detail.

The element separating portion 33a includes a groove 30a, a P⁺-type inner face layer 31a and an insulating film 32a. The groove 30a is referred to as “trench”, and is formed by selectively removing the main surface of the semiconductor substrate 10 between the photodiodes 20a and 20b. The P⁺-type inner face layer 31a is formed so as to cover the inner face of the groove 30a. The insulating film 32a is formed so as to fill the groove 30a covered with the P⁺-type inner face layer 31a. The insulating film 32a is smoothed so that its surface forms the same plane as the main surface of the semiconductor substrate 10. In this manner, the element isolating portion 33a is formed. Hereinafter, the element isolating portion formed by the STI method in this manner is referred to as “element isolating portion having the STI structure”. The structure of the element isolating portion 33b is the same as that of the element isolating portion 33a, so that the description thereof is omitted.

For the thus constituted solid-state imaging device, occurrence of color mixing is required to be reduced as much as possible. The color mixing refers to a phenomenon in which signal charges generated in the main surface of the semiconductor substrate 10 by oblique light that has passed through a photodiode (e.g., the photodiode 20b) are accumulated as signal charges in another photodiode adjacent thereto (e.g., the photodiode 20a). Therefore, the color mixing is caused, not by incident light in the perpendicular direction, but by incident light in an oblique direction, that is, oblique light, of the light incident to the main surface of the semiconductor substrate 10.

Of the oblique light incident to the main surface of the semiconductor surface 10, the amount of the oblique light that forms a large angle with respect to the main surface of the semiconductor substrate 10 is more than that of the oblique light that forms a small angle with respect to the main surface of the semiconductor substrate 10. Most of the oblique light reaches a deep portion of the semiconductor substrate 10 and generates signal charges. Therefore, the color mixing is more often caused by the signal charges generated in a deep position from the main surface in the direction of the thickness of the semiconductor substrate 10 than the signal charges generated in a shallow position from the main surface.

In order to prevent the color mixing, in Japanese Laid-Open Patent Publication 2003-142674 and the like, as shown in FIG. 8, the charge accumulating portions 23a and 23b constituting the photodiodes 20a and 20b are formed in a shallow position from the main surface of the semiconductor substrate 10. Such a structure makes it difficult that the signal charges generated in a deep portion of the semiconductor substrate 10 are accumulated as signal charges in the charge accumulating portion 23a and 23b, so that occurrence of the color mixing can be suppressed.

However, in the conventional solid-state imaging device as shown in FIG. 8, the bottom portions of the charge accumulating portions 23a and 23b are located in shallow positions from the main surface of the semiconductor substrate 10. More specifically, the bottom portions of the charge accumulating portions 23a and 23b are located in shallower positions from the main surface of the semiconductor substrate 10 than the bottom portions of the element isolating portions 33a and 33b having the STI structure. The capacities of the charge accumulating portions 23a and 23b having such shapes are small, and the amount of charges that can be accumulated is small, so that the sensitivity characteristics of the solid-state imaging device is low, which is a problem.

### SUMMARY OF THE INVENTION

Therefore, the present invention has an object to provide a solid-state imaging device having excellent sensitivity and saturation characteristics in which color mixing is prevented.

The present invention has the following features to attain the object mentioned above.

A solid-state imaging device of the present invention is directed to a solid-state imaging device in which elements are isolated by an STI method, and this solid-state imaging device includes a semiconductor substrate, a plurality of photodiodes and an element isolating portion having the STI structure.

In the solid-state imaging device of the present invention, the bottom portions of the photodiodes are located in a deeper position from the main surface of the semiconductor substrate than the bottom portions of the element isolating portions. With this structure, the capacities of the photodiodes are increased so that the amount of charges that can be accumulated is increased, and electrons obtained by photoelectric conversion can be ensured from areas up to a deep position of the semiconductor substrate. Therefore, a solid-state imaging device having excellent sensitivity and saturation characteristics can be achieved. Moreover, in the photodiodes having such a structure, as described later, a dividing line of charges occurs between adjacent photodiodes, so that the signal charges generated therebetween are directed to the desired photodiodes or a deep portion of the substrate, and therefore color mixing can be prevented.

The photodiodes are configured such that a peak of a concentration distribution in a direction of a depth of the semiconductor substrate is located in a deeper position from the main surface of the semiconductor substrate than the bottom portions of the element isolating portions, so that the peak position of the impurities constituting the photodiodes can be apart from the peak position of the concentration of the element isolating portions. Consequently, a reverse current of PN junctions, which is a leak current to the photodiodes, can be suppressed.

The side faces of the photodiodes may be in contact with side faces of the element isolating portions. With this structure, the side faces of the element isolating portions are formed of a transparent oxide film so that they can receive light, which further increases the light-receiving area of the photodiodes and thus the sensitivity characteristics can be improved. Moreover, the amount of charges that can be accumulated can be further increased, so that the saturation characteristics can be improved. In addition, also with a structure in which the photodiodes are in contact with the bottom faces of the element isolating portions, the light-receiving area of the charge accumulating portions can be increased, so that the sensitivity characteristics can be improved.

In a structure in which the photodiodes are simply in contact with the element isolating portions, depletion of the PN junctions is difficult to occur, and therefore a leak current may be increased and deterioration of image characteristics such as white spots or dark noise may occur. However, in the solid-state imaging device of the present invention, as described above, the bottom portions of the photodiodes are located in a deeper position from the main surface of the semiconductor substrate than the bottom portions of the element isolating portions, and the concentration distribution peak in the depth direction of the semiconductor substrate is located in a deeper position from the main surface of the semiconductor substrate than the bottom portions of the element isolating portions, so that the increase of a leak current can be prevented. This is because when the concentration of the photodiodes in the periphery of the element isolating portions is decreased, depletion of the PN junctions can be easily caused, so that a leak current can be suppressed also in layers below the photodiodes and the element isolating portions.

In a structure in which the semiconductor substrate includes a semiconductor layer of a first conductivity type, and a semiconductor layer of a second conductivity type formed below the semiconductor layer of the first conductivity type, the signal charges generated in a deep portion of the substrate can be diffused to the substrate side, and thus a further significant effect of preventing color mixing can be obtained.

Furthermore, instead of the semiconductor layer of the second conductivity in the above structure, the semiconductor substrate may further include a semiconductor layer of the first conductivity type having a larger impurity concentration than that of the semiconductor layer of the first conductivity type that is formed above. Also with this structure, the signal charges generated in a deep portion of the substrate can be diffused to the substrate side, and thus a further significant effect of preventing color mixing can be obtained.

As described above, according to the present invention, by providing the bottom portions of the photodiodes in a deep portion from the main surface of a semiconductor substrate than the bottom portions of the element isolating portions having the STI structure, the amount of signal charges that can be accumulated can be increased while color mixing is prevented, so that a solid-state imaging device having good sensitivity and saturation characteristics can be realized. Furthermore, by forming the photodiodes so as to be in contact with the side faces or the bottom faces of the element isolating portions, the light-receiving area can be increased. In this case, by making the concentration distribution peak in the depth direction of the semiconductor substrate in the photodiodes be located in a deeper position from the main surface of the semiconductor substrate than the bottom portions of the element isolating portions, a solid-state imaging device having good sensitivity, saturation characteristics and image characteristics without white spots and dark noise can be realized.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the structure of a solid-state imaging device;

FIG. 2 is a cross-sectional view of a solid-state imaging device of a first embodiment of the present invention;

FIGS. 3A to 3C are diagrams showing the energy distribution and the state of generated signal charges in the solid-state imaging device of the first embodiment of the present invention;

FIGS. 4A to 4F are views showing the production process of the solid-state imaging device of the first embodiment of the present invention;

FIGS. 5A and 5B are a cross-sectional view of a solid-state imaging device of a second embodiment of the present invention and a diagram showing the energy distribution and the state of generated signal charges;

FIGS. 6A and 6B are a cross-sectional view of a solid-state imaging device of a second embodiment of the present invention and a diagram showing the energy distribution and the state of generated signal charges;

FIGS. 7A and 7B are a cross-sectional view of a solid-state imaging device of a second embodiment of the present invention and a diagram showing the energy distribution and the state of generated signal charges; and

FIG. 8 is a cross-sectional view showing the structure of a conventional semiconductor device.

### DESCRIPTION OF THE PREFERRED EMBODIMENTS

### First Embodiment

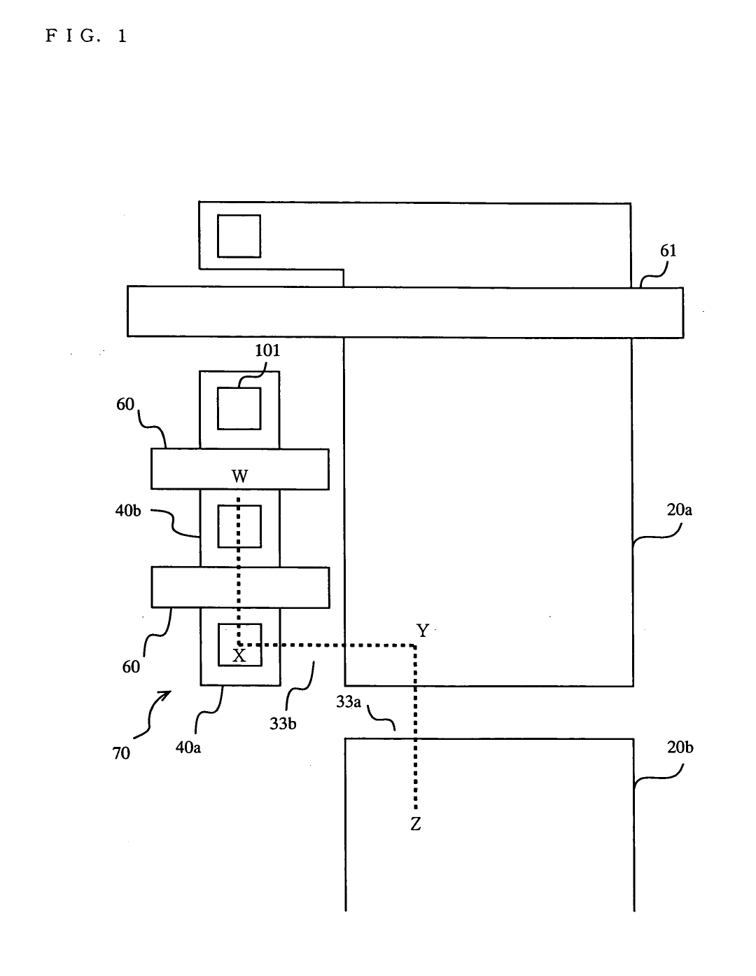

FIG. 1 is a schematic plan view of a solid-state imaging device in which elements are isolated by the STI method. The solid-state imaging device shown in FIG. 1 includes photodiodes 20a and 20b and a high voltage transistor 70, and these elements are isolated by element isolating portions 33a and 33b. The high voltage transistor 70 includes gate electrodes 60 and 61, a source diffusing layer 40a, a drain diffusing layer 40b and a contact portion 101 for contact to an upper conduction layer. The element isolating portion 33a separates between the photodiode 20a and the photodiode 20b and the element isolating portion 33b separates between the photodiode 20a and the high voltage transistor 70.

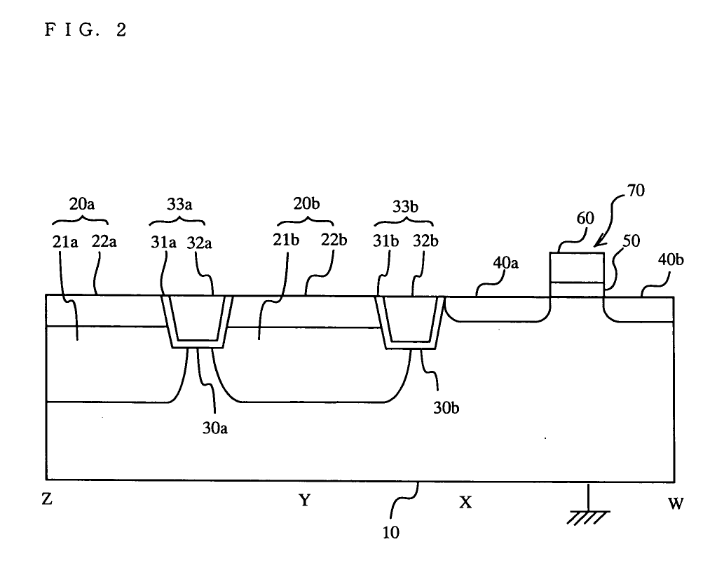

FIG. 2 is across-sectional view of a solid-state imaging device taken along the line W-X-Y-Z shown in FIG. 1. The structure of the solid-state imaging device of the first embodiment of the present invention will be described with reference to FIG. 2. The solid-state imaging device shown in FIG. 2 is a solid-state imaging device employing an amplification type MOS sensor and is formed in a semiconductor substrate 10. The semiconductor substrate 10 is a silicon substrate that serves as the base for forming a solid-state imaging device and is constituted by a P-type semiconductor layer.

The photodiode 20a is formed in the main surface of the semiconductor substrate 10 and generates signal charges having a charge amount in accordance with the intensity of incident light that is directed to the main surface of the semiconductor substrate 10 and accumulates the generated signal charges. The photodiode 20a is a buried PNP photodiode including a P⁺-type surface layer 22a formed in the vicinity of the surface of the semiconductor substrate 10 and a charge accumulating portion 21a formed below the P⁺-type surface layer 22a.

The P⁺-type surface layer 22a is formed by introducing P-type impurities in the main surface of the semiconductor substrate 10 by ion implantation so as to have a larger impurity concentration than that of the P-type semiconductor layer of the semiconductor substrate 10. The charge accumulating portion 21a is an N-type impurity layer and forms a PN junction with the P⁺-type surface layer 22a so that the charge accumulating portion 21a generates signal charges having a charge amount in accordance with the intensity of incident light and accumulates the generated signal charges. The charge accumulating portion 21a is formed by introducing N-type impurities to the main surface of the semiconductor substrate 10 by ion implantation and diffusing thermally the introduced impurities. The photodiode 20b has the same structure as that of the photodiode 20a, so that the description thereof is omitted.

The high voltage transistor 70 includes a source diffusion layer 40a, a drain diffusion layer 40b, a gate insulating film 50 and a gate electrode 60. The source diffusion layer 40a and the drain diffusion layer 40b are formed by introducing N-type impurities to the main surface of the semiconductor substrate 10. The gate insulating film 50 is formed of a silicon oxide film or the like in an area between the source diffusion layer 40a and the drain diffusion layer 40b on the surface of the semiconductor substrate 10. The gate electrode 60 is formed of a polysilicon film or the like on the gate insulating film 50.

The element isolating portion 33a is an element isolating portion having an STI structure and includes a groove 30a, a P⁺-type inner face layer 31a and an insulating film 32a. The groove 30a is referred to as “trench”, and is formed by selectively removing the main surface of the semiconductor substrate 10 between the photodiodes 20a and 20b. The P⁺-type inner face layer 31a is formed so as to cover the inner face of the groove 30a. The insulating film 32a is formed so as to fill the groove 30a whose inner surface is covered with the P⁺-type inner face layer 31a. The insulating film 32a is smoothed so that its surface forms the same plane as the main surface of the semiconductor substrate 10. In this manner, the element isolating portion 33a is formed. The structure of the element isolating portion 33b is the same as that of the element isolating portion 33a, so that the description thereof is omitted.

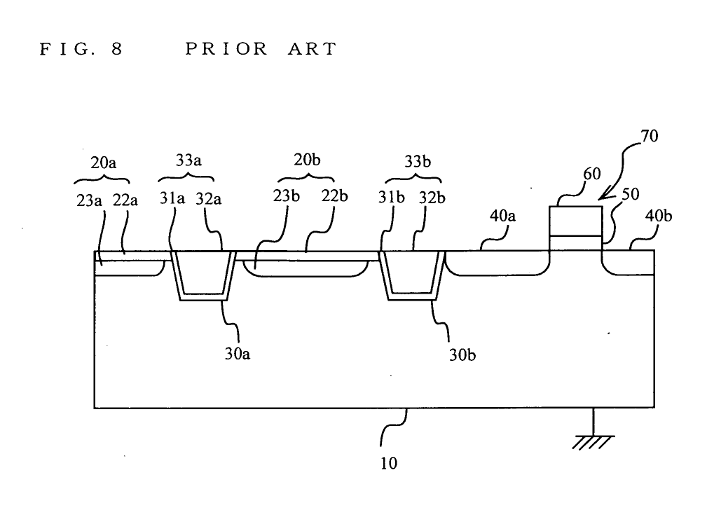

The solid-state imaging device of this embodiment is different from the conventional solid-state imaging device shown in FIG. 8 in that the bottom portions of the photodiodes 20a and 20b are located in positions deeper from the main surface of the substrate than the bottom portions of the element isolating portions 33a and 33b. More specifically, the bottom portions of the charge accumulating portions 21a and 21b constituting the photodiodes 20a and 20b are located in positions deeper from the main surface of the substrate than the bottom portions of the grooves 30a and 30b constituting the element isolating portions 33a and 33b. In the present invention, the phrase “the bottom portions of the photodiodes 20a and 20b are located in positions deeper from the main surface of the substrate than the bottom portions of the element isolating portions 33a and 33b” includes that the case where the bottom portions of the photodiodes 20a and 20b are located in the same positions with respect to the direction of the substrate thickness as the bottom portions of the element isolating portions 33a and 33b. With this structure, the capacities of the photodiodes 20a and 20b are increased so that the amount of charges that can be accumulated is increased, and electrons obtained by photoelectric conversion can be ensured from areas up to a deep position of the semiconductor substrate 10. Therefore, a solid-state imaging device having better sensitivity and saturation characteristics than conventional solid-state imaging devices can be achieved. It should be noted that as long as the bottom portions of the photodiodes 20a and 20b are located in a deeper position from the main surface of the substrate than the bottom portions of the element isolating portions 33a and 33b, there is no limitation regarding the limit thereof.

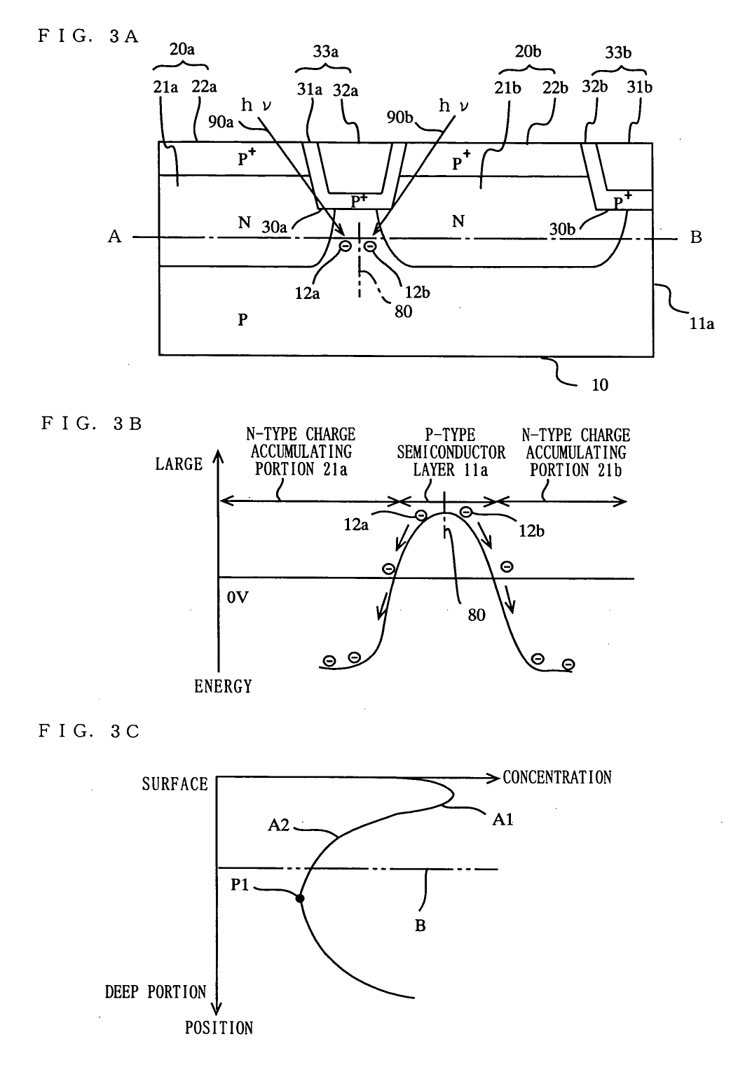

In this embodiment, the photodiodes 20a and 20b have such a shape as described above, so that not only can the photoelectric conversion area and the charge capacity be increased, but also can color mixing be prevented from occurring. The reason for this will be described with reference to FIGS. 3A and 3B. FIG. 3A is a schematic view showing a relevant portion of the solid-state imaging device shown in FIG. 2. FIG. 3B is a diagram for illustrating the energy distribution along the line A-B in the solid-state imaging device shown in FIG. 3A.

In a solid-state imaging device, color mixing is caused by the fact that signal charges generated inside the semiconductor substrate 10 by oblique light that has passed through a photodiode (e.g., photodiode 20b) are accumulated as signal charges in another photodiode adjacent thereto (e.g., the photodiode 20a). For example, in FIG. 3A, a signal charge 12a generated by incident light (hν) 90a having passed through the photodiode 20a enters the charge accumulating portion 21b constituting the photodiode 20b, so that color mixing occurs. Alternatively, a signal charge 12b generated by incident light (hν) 90b having passed through the photodiode 20b enters the charge accumulating portion 21a constituting the photodiode 20a, so that color mixing occurs.

However, in the solid-state imaging device of this embodiment, as described above, the bottom portions of the charge accumulating portions 21a and 21b are located in deep positions from the main surface of the substrate. Therefore, as shown in FIG. 3B, an energy distribution peak having an upwardly convex shape is generated between the adjacent charge accumulating portions 21a and 21b, that is, a P-type semiconductor layer 11a. This energy distribution peak is referred to as “dividing line of charges 80”. Such a dividing line of charges 80 is formed, so that the signal charge 12a generated by light that has passed through the charge accumulating portion 21a is directed to the side of the charge accumulating portion 21a, as shown by an arrow in FIG. 3B, whereas the signal charge 12b generated by light that has passed through the charge accumulating portion 21b is directed to the side of the charge accumulating portion 21b. Thus, the signal charges 12a and 12b are accumulated in the charge accumulating portions 21a and 21b where they are to be accumulated, respectively. Therefore, in the solid-state imaging device of this embodiment, color mixing caused by signal charges generated between the adjacent photodiodes 20a and 20b can be prevented.

Furthermore, the side faces of the photodiodes 20a and 20b are in contact with the side faces of the element isolating portions 33a and 33b. With this structure, the capacities of the photodiodes 20a and 20b become even larger than those with the conventional charge accumulating portions 23a and 23b. Moreover, the side faces of the element isolating portions 33a and 33b are formed of a transparent oxide film so that they can receive light, which increases the light-receiving area of the photodiodes 20a and 20b and thus further increases the photodiode region, leading to further increase in the amount of charges that can be accumulated.

Furthermore, the photodiodes 20a and 20b are partially in contact with the bottom face of the element isolating portions 33a and 33b. With such a structure, the light-receiving area can be increased and the photoelectric conversion region can be deep, so that the sensitivity characteristics can be improved.

Since simply bringing the photodiodes 20a and 20b into contact with the element isolating portions 33a and 33b makes it difficult to cause depletion of the PN junctions, a leak current may be increased and deterioration of image characteristics such as white spots or dark noise may occur. Therefore, the solid-state imaging device of the present invention is configured such that the concentration distribution peak in the depth direction of the semiconductor substrate in the photodiodes 20a and 20b is located in a deeper position from the main surface of the semiconductor substrate 10 than the bottom portions of the element isolating portions 33a and 33b, so that the increase of a leak current can be prevented.

FIG. 3C shows the concentration distribution in the direction of the depth of the substrate of the photodiodes 20a and 20b. A curve A1 shows the concentration distribution of the P⁺-type surface layers 22a and 22b, and a curve A2 shows the concentration distribution of the N-type charge accumulating portions 21a and 21b. A broken line B shows the position of the bottom portions of the element isolating portions 33a and 33b. In this case, when the solid-state imaging device is configured such that the peak P1 in the concentration distribution of the N-type charge accumulating portions 21a and 21b shown by the curve A2 is located in a deeper portion of the substrate than the bottom portions of the element isolating portions 33a and 33b shown in the broken line B, so that the increase of a leak current can be prevented. This is because depletion of the PN junctions can be easily caused by decreasing the concentration of the charge accumulating portions 21a and 21b in the periphery of the element isolating portions 33a and 33b, so that a leak current can be suppressed also in layers below the photodiodes 20a and 20b and the element isolating portions 33a and 33b.

Furthermore, the photodiodes 20a and 20b having such a concentration distribution can keep the peak position P1 of the impurity concentration of the charge accumulating portions 21a and 21b apart from the peak position of the concentration of the element isolating portions 33a and 33b. Consequently, a reverse current of PN junctions, which is a leak current to the photodiodes 20a and 20b, can be suppressed.

In the thus configured solid-state imaging device, for example, the depth of the grooves 30a and 30b from the surface of the substrate is about 0.3 μm, the depth of the charge accumulating portions 21a and 21b from the surface of the substrate is about 0.8 μm, the depth of the P⁺-type surface layer 22a and 22b from the surface of the substrate is about 0.2 μm, and the depth of the source diffusion layer 40a and the drain diffusion layer 40b from the surface of the substrate is about 0.1 μm.

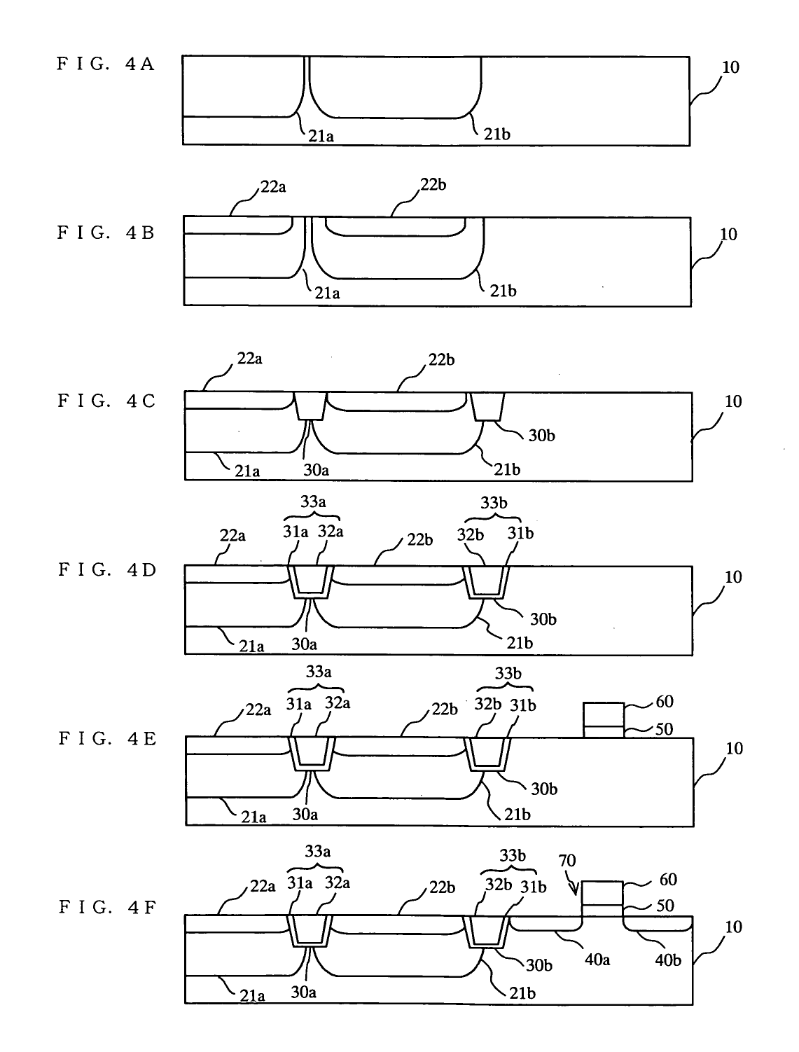

Hereinafter, a method for producing the solid-state imaging device having such a configuration will be described with reference to FIG. 4. FIGS. 4A to 4F are cross-sectional views of the semiconductor substrate and the above of its surface at each stage of producing the solid-state imaging device shown in FIG. 2.

FIG. 4A shows a state in which the charge accumulating portions 21a and 21b are formed in the main surface of the semiconductor substrate 10. In order to obtain a substrate in this state, first, a resist pattern having openings formed in areas in which the charge accumulating portions 21a and 21b are to be formed is provided by a known method on the main surface of the P-type semiconductor substrate 10. Using this resist pattern as a mask, ions implantation is performed with arsenic (As), which is an N-type impurity, at a high energy. More specifically, As ions are implanted at 650 KeV and 1.8×10¹²/cm². Thus, the charge accumulating portions 21a and 21b are formed in the main surface of the semiconductor substrate 10. The depth of the charge accumulating portions 21a and 21b from the substrate surface is about 0.8 μm.

FIG. 4B shows a state in which the P⁺-type surface layers are formed in the charge accumulating portions 21a and 21b. In order to obtain a substrate in this state, first, a resist pattern having openings formed in areas in which the P⁺-type surface layers 22a and 22b are to be formed is provided by a known method on the surface of the semiconductor substrate 10. Using this resist pattern as a mask, P-type impurity (e.g.,boron) ions are implanted. Thus, the P⁺-type surface layers 22a and 22b are formed inside the charge accumulating portions 21a and 21b. The depth of the P⁺-type surface layers 22a and 22b from the substrate surface is about 0.2 μm.

FIG. 4C shows a state in which the grooves 30a and 30b for isolating elements are formed in the main surface of the semiconductor substrate 10. Such grooves 30a and 30b are formed by performing a dry etching treatment in areas in which the element isolating portions are to be formed. The depth of the grooves 30a and 30b is about 0.3 μm.

FIG. 4D shows a state in which the element isolating portions 33a and 33b are formed. In order to form such element isolating portions, first, ion implantation is performed at a low acceleration toward the internal portion of the grooves 30a and 30b. More specifically, boron (B) ions are implanted at 30 KeV and 3.2×10¹³/cm². Thus, the P⁺-type inner face films 31a and 31b are formed in the inner surfaces of the grooves 30a and 30b. Next, the grooves 30a and 30b covered with the inner face films 31a and 31b are filled with insulating films 32a and 32b such as oxide films and smoothed. Thus, the element isolating portions 33a and 33b having the STI structure can be formed.

FIG. 4E shows a state in which the gate insulating film 50 and the gate electrode 60 are formed on the semiconductor substrate 10. In order to obtain a substrate in this state, first, a silicon oxide film (SiO₂ film) is deposited in a thickness of 9 nm on the surface of the semiconductor substrate 10 by thermal oxidation or a CVD (chemical vapor deposition) method. Then, a polysilicon oxide film is deposited in a thickness of 160 nm on the SiO₂ film by a CVD method. Then, these films are subjected to photolithography and dry-etching so that necessary patterns are formed, and thus the gate insulating film 50 and the gate electrode 60 are formed.

FIG. 4F shows a state in which the source diffusion layer 40a and the drain diffusion layer 40b are formed in the main surface of the semiconductor substrate 10. In order to form such element isolating portions, first, ions of N-type impurities are implanted in the main surface of the semiconductor substrate 10, using the gate electrode 60 as a mask. More specifically, arsenic (As) ions are implanted at 50 KeV and 2.0×10¹⁵/cm². Thus, the source diffusion layer 40a and the drain diffusion layer 40b are formed in the main surface of the semiconductor substrate 10, and a high voltage MOS transistor 70 is formed.

### Second Embodiment

In this embodiment, a solid-state imaging device having a structure in which color mixing due to signal charges generated even in a deep portion in the substrate can be prevented will be described. The solid-state imaging device of this embodiment has substantially the same structure as the solid-state imaging device of the first embodiment, so that only differences therebetween will be described in the following.

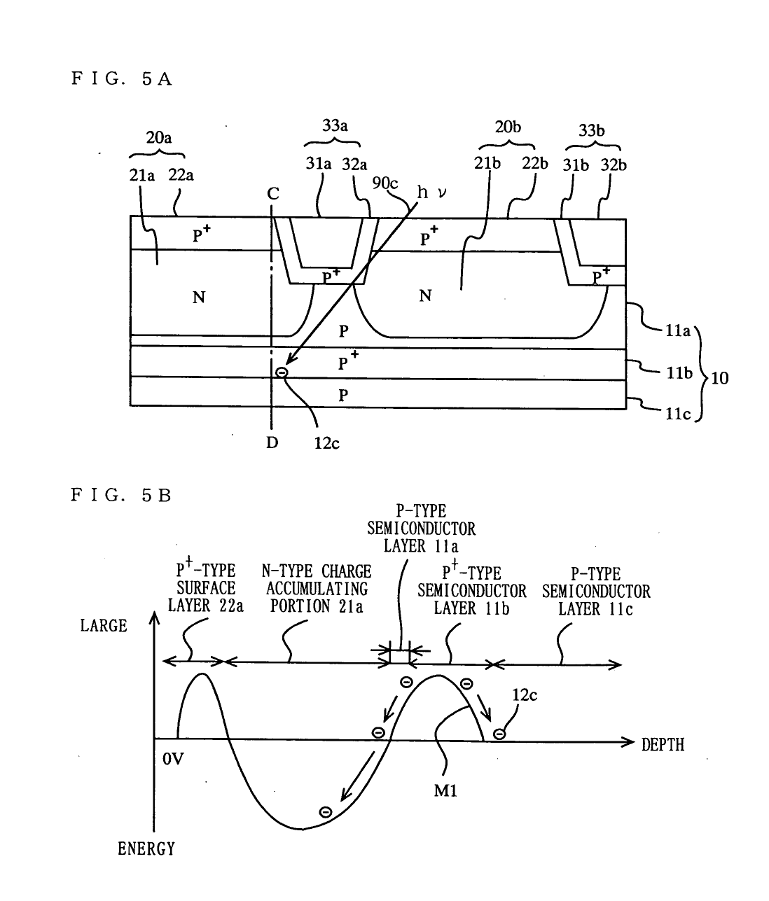

FIG. 5A is a schematic view showing a cross-sectional structure of a solid-state imaging device of the second embodiment of the present invention. FIG. 5B is a diagram for illustrating the energy distribution along the line C-D in the solid-state imaging device shown in FIG. 5A. In FIG. 5A, the semiconductor substrate 10 is constituted by a P-type semiconductor layer 11a that is located on the surface, a P⁺-type semiconductor layer 11b formed below that layer, and a P-type semiconductor layer 11c that is located in the bottom portion. In this embodiment, the P⁺-type semiconductor layer 11b is formed in a position deeper from the main surface of the substrate than the bottom portion of the photodiodes 20a and 20b.

With this structure, the energy distribution along the direction of the substrate depth of the semiconductor substrate 10 has an energy peak (M1) having an upwardly convex shape in a deep portion of the substrate, as shown in FIG. 5B. Therefore, for example, in FIG. 5A, a signal charge 12c generated in a deep portion in the substrate by incident light (hν) 90c that has passed through the photodiode 20b is directed to the side of the P-type semiconductor layer 11c (in the direction shown by an arrow), as shown in FIG. 5B. Thus, by constituting a solid-state imaging device such that a semiconductor layer 11b having a larger impurity concentration is further provided below the semiconductor layer 11a in which the photodiodes 20a and 20b are formed so that the signal charge 12c generated in a deep portion of the substrate is directed to a deeper portion of the substrate, color mixing due to signal charges generated in a deep portion of the substrate can be prevented, in addition to the effect of the first embodiment.

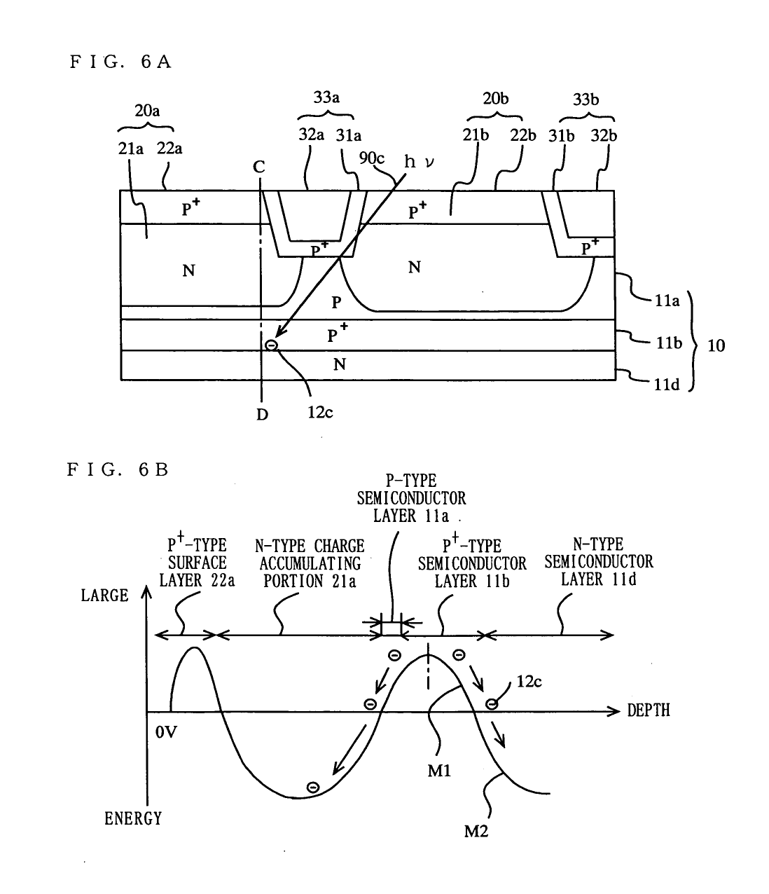

Furthermore, in order for signal charges generated in a deep portion of the substrate to flow toward the substrate side in a more reliable manner, the semiconductor substrate 10 is configured in the manner as shown in FIG. 6A. In FIG. 6A, the semiconductor substrate 10 is constituted by a P-type semiconductor layer 11a that is located on the surface, a P⁺-type semiconductor layer 11b formed below that layer, and an N-type semiconductor layer 11d that is located in the bottom portion. In this embodiment, the P⁺-type semiconductor layer 11b is formed in a position deeper from the main surface of the substrate than the bottom portion of the photodiodes 20a and 20b. The typical impurity concentrations of the thus constituted semiconductor substrate 10 are about 1×10¹⁴ to 1×10¹⁵/cm² for the P-type semiconductor layer 11a, about 1×10¹⁶ to 1×10¹⁷/cm² for the P⁺-type semiconductor layer 11b, and about 1×10¹⁴ to 1×10¹⁵/cm² for the N-type semiconductor layer 11d.

FIG. 6B is a diagram for illustrating the energy distribution along the line C-D in the solid-state imaging device shown in FIG. 6A. As shown in FIG. 6A, in the solid-state imaging device in which the N-type semiconductor layer 11d having a low energy is provided adjacent to the P⁺-type semiconductor layer 11b, a slope (M2) directed toward the lower side is generated adjacent to an energy peak (M1) having an upwardly convex shape, as shown in FIG. 6B. Therefore, for example, in FIG. 6A, the signal charge 12c generated in a deep portion of the substrate that has passed through the charge accumulating portion 21b is more easily directed in the direction shown by an arrow, that is, toward the side of the N-type semiconductor layer 11d, as shown in FIG. 6B.

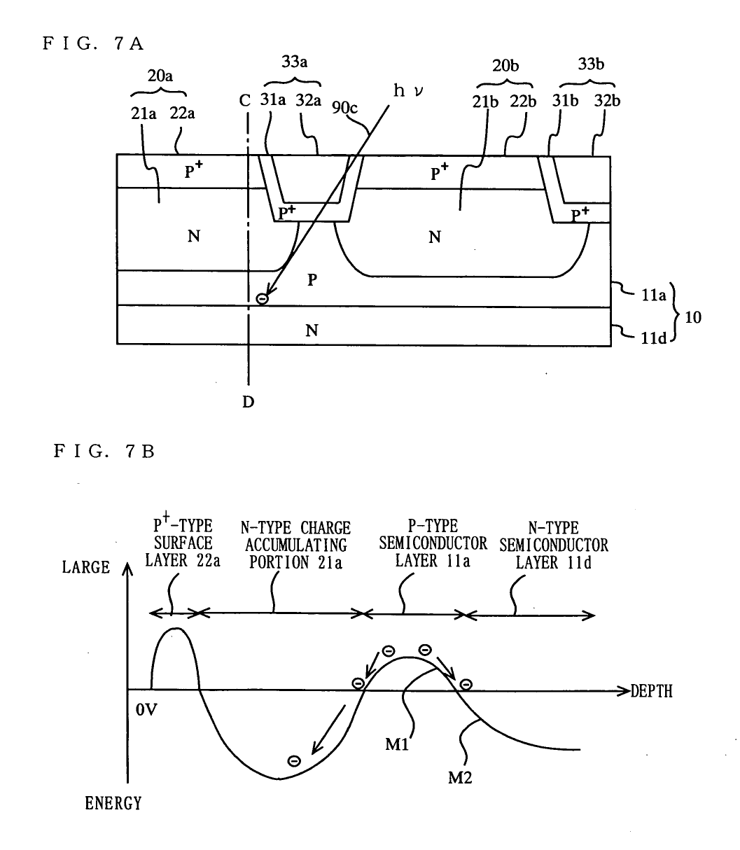

Furthermore, the semiconductor substrate 10 may be such that a P-type semiconductor layer 11a is formed directly on the N-type semiconductor layer 11d, as shown in FIG. 7A. The N-type semiconductor layer 11d is formed in a deeper position from the main surface of the substrate than the bottom portion of the photodiodes 20a and 20b. Also with this structure, the same energy distribution as shown in FIG. 6B can be obtained, as shown in FIG. 7B.

As shown in FIGS. 6A and 7A, in order to form a P-type semiconductor layer on an N-type semiconductor layer, an N-type silicon substrate is used and high energy is implanted to this silicon substrate a plurality of times so that a deep P-type semiconductor layer is formed. For example, in the case of the semiconductor substrate 10 shown in FIG. 7A, P-type impurities (e.g., boron) ions are implanted to an N-type silicon substrate by five stages. The ion implantation in this case is such that 1.0×10¹¹/cm² at 400 KeV, 1.0×10¹¹/cm² at 800 KeV, 1.0×10¹¹/cm² at 1200 KeV, 1.0×10¹¹/cm² at 1600 KeV, and 2.0×10¹¹/cm² at 1800 KeV.

In the solid-state imaging device disclosed in Japanese Laid-Open Patent Publication 2003-142674 that is cited as a conventional technique, an N-type impurity layer encloses the periphery of the element isolating regions having the STI structure in order to suppress a leak current in the peripheral portion of the element isolating regions. Therefore, as the semiconductor substrate constituting a solid-state imaging device, only a P-type semiconductor substrate can be used. However, in the present invention can be applied, not only to a solid-state imaging device using a P-type semiconductor substrate, but also to a solid-state imaging device using an N-type semiconductor substrate, as described above.

In the above embodiments, the charge accumulating portions 21a and 21b constituting the photodiodes 20a and 20b are in contact with the bottom portions of the grooves 30a and 30b. However, the bottom portions do not necessarily have to be in contact with each other. Furthermore, in the above embodiments, the side faces of the charge accumulating portions 21a and 21b are in contact with the side faces of the grooves 30a and 30b. However, the side faces do not necessarily have to be in contact with each other.

Furthermore, the solid-state imaging devices of the above embodiments have been described by taking an MOS solid-state imaging device as an example. However, the present invention can be applied to CCD (charge coupled device) or a CMOS sensor.

The solid-state imaging device of the present invention is characterized by providing high charge accumulating amounts, and preventing color mixing, so that the present invention can be used preferably for an MOS solid-state imaging device having an element isolating structure by the STI method. More specifically, the present invention can be used preferably for a solid-state imaging device used in mobile telephones with a camera, video cameras, and digital still cameras or a line sensor used in a printer or the like.

While the invention has been described in detail, the foregoing description is in all aspects illustrative and not restrictive. It is understood that numerous other modifications and variations can be devised without departing from the scope of the invention.

1. A solid-state imaging device comprising:
a semiconductor substrate;
a plurality of photodiodes that are formed in a main surface of the semiconductor substrate and generate and accumulate signal charges in accordance with an intensity of incident light; and
an element isolating portion formed by filling a groove formed in the main surface of the semiconductor substrate with an insulating film in order to separate between adjacent photodiodes,
wherein bottom portions of the photodiodes are located in a deeper position from the main surface of the semiconductor substrate than bottom portions of the element isolating portions.

2. The solid-state imaging device according to claim 1, wherein a peak of a concentration distribution in a direction of a depth of the semiconductor substrate of the photodiodes is located in a deeper position from the main surface of the semiconductor substrate than the bottom portions of the element isolating portions.

3. The solid-state imaging device according to claim 2, wherein side faces of the photodiodes are in contact with side faces of the element isolating portions.

4. The solid-state imaging device according to claim 2, wherein the photodiodes are in contact with the bottom portions of the element isolating portions.

5. The solid-state imaging device according to claim 1, wherein the semiconductor substrate comprises:
a semiconductor layer of a first conductivity type for forming the photodiodes, and
a semiconductor layer of a second conductivity type formed below the semiconductor layer of the first conductivity type.

6. The solid-state imaging device according to claim 1, wherein the semiconductor substrate comprises:
a semiconductor layer of a first conductivity type for forming the photodiodes, and
a semiconductor layer of the first conductivity type that is formed below the semiconductor layer and has a larger impurity concentration than that of the semiconductor layer.
